(19) United States
(12) Patent Application Publication
(10) Pub. No.: US 2018/0282895 A1
(43) Pub. Date: Oct. 4, 2018

(54) PLATING METHOD

(71) Applicant: EBARA CORPORATION, Tokyo (JP)

(72) Inventors: Yohei WAKUDA, Tokyo (JP); Mizuki NAGAI, Tokyo (JP); Masashi SHIMOYAMA, Tokyo (JP)

(21) Appl. No.: 15/934,620

(22) Filed: Mar. 23, 2018

(30) Foreign Application Priority Data
Mar. 30, 2017 (JP) 2017-067836

(51) Int. Cl. C25D 21/18; C25D 3/54; H01L 21/768

(52) U.S. Cl. CPC C25D 21/18; C25D 17/10; H01L 21/76873; C25D 3/54

(57) ABSTRACT

There is provided a method of supplying an indium ion to a plating solution for electrolytic plating using an insoluble anode. The method includes a step of preparing an acidic plating solution and a step of immersing indium metal in the plating solution and dissolving the indium metal in the plating solution without voltage application to the indium metal.

### CROSS-REFERENCE TO RELATED APPLICATION

This application is based upon and claims benefit of priority from Japanese Patent Application No. 2017-067836 filed on Mar. 30, 2017, the entire contents of which are incorporated herein by reference.

### TECHNICAL FIELD

The present invention relates to a plating method.

### BACKGROUND ART

Processes that have conventionally been performed include a process of forming a piece of wiring in a fine wiring groove, hole, or resist opening which is provided at a surface of a substrate, such as a semiconductor wafer, and a process of forming a bump (a projection-shaped electrode) to be electrically connected to an electrode or the like of a package at a surface of a substrate. As methods for forming such a piece of wiring or a bump, for example, an electrolytic plating method, a vapor deposition method, a printing method, a ball bump method, and the like are known. With increase in the number of I/Os or pitch narrowing in a semiconductor chip, an electrolytic plating method which allows miniaturization and is relatively stable in performance is becoming more popular.

A device which performs electrolytic plating generally includes an anode and a substrate arranged so as to face each other in a plating bath holding a plating solution, and a voltage is applied to the anode and the substrate. With this application, a plating film is formed on a surface of the substrate.

Plating with indium by an electrolytic plating method is conventionally known. In a case where indium-plating is performed by an electrolytic plating method, indium ions in a plating solution are consumed with the progress of the plating processing. For this reason, indium ions need to be supplied to the plating solution with the progress of the plating processing.

Examples of a known method for supplying indium ions to a plating solution include a method that supplies a commercially available concentrated indium solution to a plating solution, and a method that dissolves indium metal by electrolysis. It is also known that, in a case where a soluble anode containing indium metal is used, the anode dissolves upon application of a voltage to the anode to supply indium ions to a plating solution.

### CITATION LIST

### Patent Literature

PTL 1: Japanese Patent Laid-Open No. 2009-287118

### SUMMARY OF INVENTION

### Technical Problem

However, a concentrated indium solution is generally expensive, which leads to the problem of high running costs of plating processing. Additionally, supply of the concentrated indium solution to a plating solution raises the concentration of anionic species in the plating solution and may adversely affect the plating solution and a plating film in some cases.

A case where indium metal is dissolved by electrolysis needs provision of a power source for applying a negative voltage to an anode and indium metal and a positive voltage to the anode in a plating apparatus. This creates the need for a facility for electrolytic dissolution and causes the problem of increase in the complexity of the configuration of the plating apparatus. In a case where a soluble anode containing indium metal is used, indium concentration rises during voltage application to the soluble anode, and control of the indium concentration in a plating solution is difficult.

Dissolution of indium oxide in a plating solution is also conceivable. A metal oxide, however, is generally hardly soluble in water and is low in a rate of dissolution in an acidic solution. Indium oxide is thus considered low in a rate of dissolution in a plating solution, and supply of sufficient indium ions with respect to a plating rate may be difficult. Additionally, dissolution of indium oxide in a plating solution increases anionic species of an indium compound in the plating solution, which may adversely affect the plating solution and a plating film.

The present invention has been made in view of the above-described problems. An object of the present invention is to simply and inexpensively supply indium ions to a plating solution.

### Solution To Problem

According to an aspect of the present invention, there is provided a method for supplying an indium ion to a plating solution for electrolytic plating using an insoluble anode. The method includes a step of preparing an acidic plating solution containing an indium ion and a step of immersing indium metal in the plating solution and dissolving the indium metal in the plating solution without voltage application to the indium metal.

### BRIEF DESCRIPTION OF DRAWINGS

FIG. 1 is a general arrangement drawing of a plating apparatus according to the present embodiment;

FIG. 2 is a schematic view of a plating unit shown in FIG. 1;

FIG. 3 is a graph showing the amount of decrease in indium metal with respect to time when the indium metal is immersed in an acidic indium plating solution;

FIG. 4 is a graph showing change of indium metal concentration in an acidic indium plating solution with respect to time when indium metal is immersed in the plating solution;

FIG. 5 is a schematic view showing a dissolution bath of a plating unit according to another embodiment;

FIG. 6 is a schematic view showing a dissolution bath of a plating unit according to another embodiment; and

FIG. 7 is a schematic view showing a dissolution bath of a plating unit according to another embodiment.

### DESCRIPTION OF EMBODIMENTS

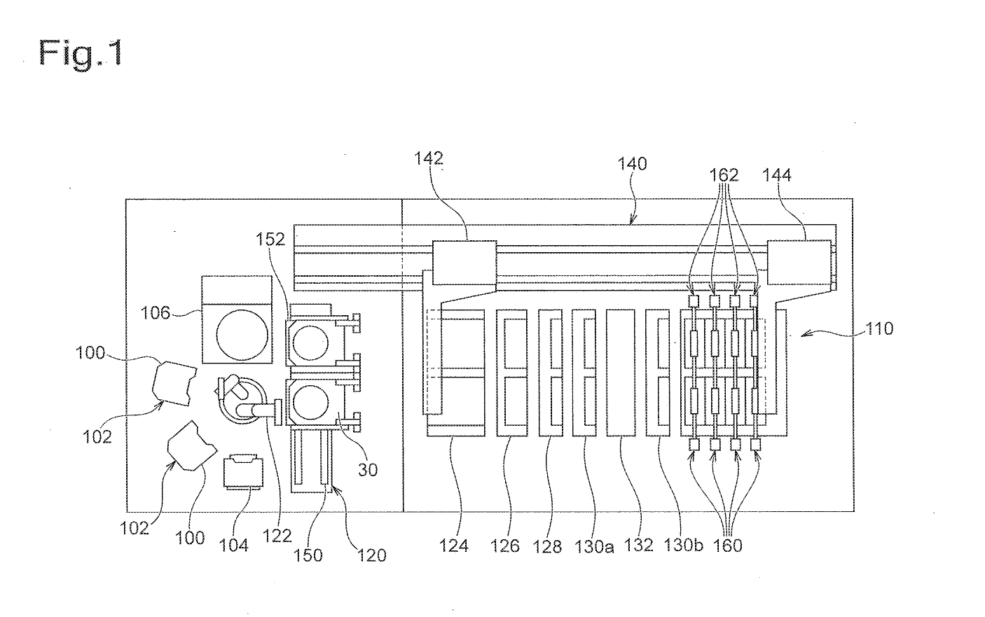

Embodiments of the present invention will be described below with reference to the drawings. Components which are the same as or corresponding to each other in the drawings to be referred to in the following description are denoted by the same reference numerals, and a duplicate description thereof will be omitted. FIG. 1 is a general arrangement drawing of a plating apparatus according to the present embodiment. As shown in FIG. 1, the plating apparatus includes two cassette tables 102, an aligner 104, and a spin rinse dryer 106. Each cassette table 102 has a cassette 100 mounted thereon which stores substrates, such as a semiconductor wafer. The aligner 104 aligns the position of an orientation flat, a notch, or the like of a substrate with a predetermined direction. The spin rinse dryer 106 dries a substrate after plating processing by spinning the substrate at high speed. A substrate attachment and detachment portion 120 which has substrate holders 30 mounted thereon and attaches or detaches substrates to or from the substrate holders 30 is provided near the spin rinse dryer 106. A substrate transport device 122 composed of a transport robot which transports a substrate between the units 100, 104, 106, and 120 is arranged among the units.

The substrate attachment and detachment portion 120 includes a flat plate-shaped mounting plate 152 which is slidable in a lateral direction along rails 150. Two substrate holders 30 are horizontally placed side by side on the mounting plate 152. After a substrate is passed between one substrate holder 30 and the substrate transport device 122, the mounting plate 152 is slid in the lateral direction, and a substrate is passed between the other substrate holder 30 and the substrate transport device 122.

The plating apparatus further includes stockers 124, pre-wetting baths 126, pre-soaking baths 128, first washing baths 130a, a blow bath 132, second washing baths 130b, and a plating unit 110. In the stockers 124, keeping of the substrate holders 30 in storage and temporary placement of the substrate holders 30 are performed. In the pre-wetting baths 126, substrates are immersed in pure water. In the pre-soaking baths 128, oxide films at surfaces of conductive layers, such as a seed layer, formed at surfaces of substrates are removed by etching. In the first washing baths 130a, substrates after pre-soaking are washed together with the substrate holders 30 using a wash solution (e.g., pure water). In the blow bath 132, substrates after washing are drained. In the second washing baths 130b, substrates after plating are washed together with the substrate holders 30 using a wash solution. The substrate attachment and detachment portion 120, the stockers 124, the pre-wetting baths 126, the pre-soaking baths 128, the first washing baths 130a, the blow bath 132, the second washing baths 130b, and the plating unit 110 are arranged in this order. The plating unit 110 is configured to indium-plate a substrate surface and includes plating baths, a management bath, and a dissolution bath, as will be described later.

The plating apparatus includes a substrate holder transport device 140 which is located lateral to the above-described pieces of equipment and adopts, for example, a linear motor system. The substrate holder transport device 140 transports the substrate holders 30 together with substrates between the pieces of equipment. The substrate holder transport device 140 includes a first transporter 142 and a second transporter 144. The first transporter 142 is configured to transport substrates between the substrate attachment and detachment portion 120, the stockers 124, the pre-wetting baths 126, the pre-soaking baths 128, the first washing baths 130a, and the blow bath 132. The second transporter 144 is configured to transport substrates between the first washing baths 130a, the second washing baths 130b, the blow bath 132, and the plating unit 110. The plating apparatus need not include the second transporter 144 and may include only the first transporter 142.

The plating unit 110 has paddle driving portions 160 and paddle driven portions 162 arranged on two sides. The paddle driving portions 160 and paddle driven portions 162 drive paddles as stirring rods which are located inside the respective plating baths and stir a plating solution in the plating baths.

An example of a series of plating processes by the plating apparatus will be described. First, one substrate is taken out from each of the cassettes 100 mounted on the cassette tables 102 by the substrate transport device 122 and is transported to the aligner 104. The aligner 104 aligns the position of an orientation flat, a notch, or the like with the predetermined direction. The substrate after the alignment with the direction by the aligner 104 is transported to the substrate attachment and detachment portion 120 by the substrate transport device 122.

As for the substrate attachment and detachment portion 120, two substrate holders 30 held in the stockers 124 are simultaneously grasped by the first transporter 142 of the substrate holder transport device 140 and are transported to the substrate attachment and detachment portion 120. The two substrate holders 30 are simultaneously and horizontally placed on the mounting plate 152 of the substrate attachment and detachment portion 120. In this state, the substrate transport device 122 transports the substrates to the respective substrate holders 30, and the substrate holders 30 hold the transported substrates.

The two substrate holders 30 holding the substrates are simultaneously grasped by the first transporter 142 of the substrate holder transport device 140 and are housed in the pre-wetting baths 126. The substrate holders 30 holding the substrates treated in the pre-wetting baths 126 are transported to the pre-soaking baths 128 by the first transporter 142. In the pre-soaking baths 128, an oxide film on each substrate is etched. The substrate holders 30 holding the substrates are then transported to the first washing baths 130a. Surfaces of the substrates are washed with pure water held in the first washing baths 130a.

The substrate holders 30 holding the substrates after the water washing are transported from the first washing baths 130a to the plating unit 110 by the second transporter 144 and are housed in respective ones of the plating baths filled with the indium plating solution. The second transporter 144 sequentially repeats the above-described procedure and sequentially houses the substrate holders 30 holding substrates in the plating baths of the plating unit 110.

In each plating bath, a plating voltage is applied between an anode and a substrate in the plating bath, and the paddle driving portion 160 and the paddle driven portion 162 simultaneously reciprocate a paddle in parallel with a surface of the substrate, thereby indium-plating the surface of the substrate.

After the plating, the two substrate holders 30 holding the substrates after the plating are simultaneously grasped by the second transporter 144, are transported to the second washing baths 130b, and are immersed in pure water held in the second washing baths 130b, thereby washing the surfaces of the substrates with pure water. The substrate holders 30 are then transported to the blow bath 132 by the second transporter 144, and water droplets deposited on the substrate holders 30 are removed by air blowing or the like. After that, the substrate holders 30 are transported to the substrate attachment and detachment portion 120 by the first transporter 142.

In the substrate attachment and detachment portion 120, the treated substrates are taken out from the substrate holders 30 by the substrate transport device 122 and are transported to the spin rinse dryer 106. The spin rinse dryer 106 dries the substrates after the plating processing by high-speed spinning. The dried substrates are returned to the cassettes 100 by the substrate transport device 122.

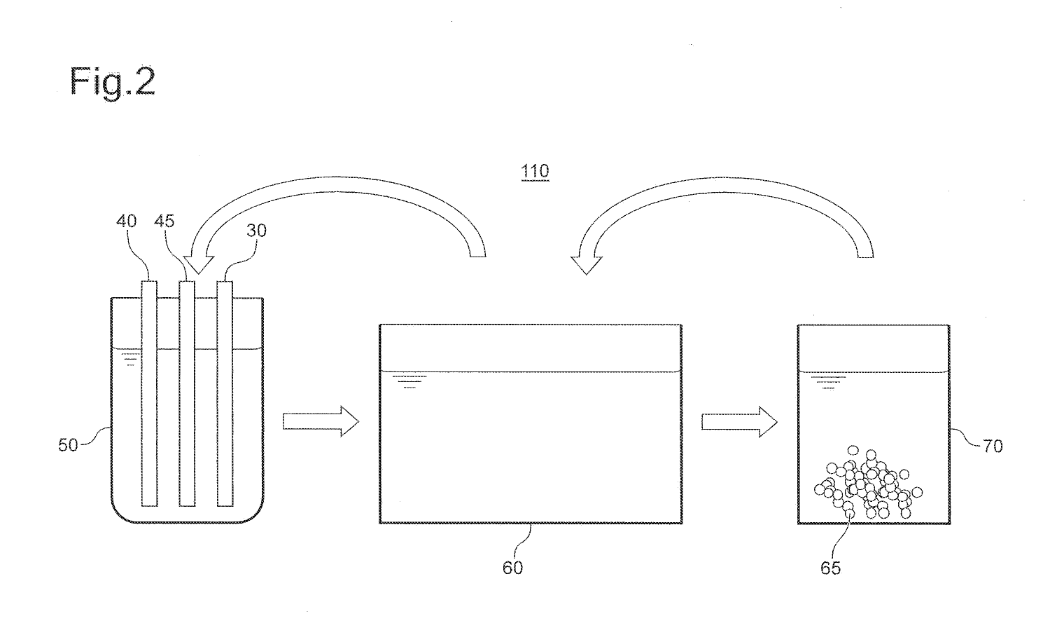

FIG. 2 is a schematic view of the plating unit 110 shown in FIG. 1. As shown in FIG. 2, the plating unit 110 includes a plating bath 50 which holds a plating solution, a management bath 60 for controlling indium metal concentration in the plating solution, and a dissolution bath 70 for dissolving indium metal in the plating solution. The plating bath 50 contains an anode holder 40 which holds an anode (not shown), the substrate holder 30 that holds a substrate (not shown), and a paddle 45 which stirs the plating solution in the plating bath 50.

The plating bath 50, the management bath 60, and the dissolution bath 70 according to the present embodiment each hold an acidic plating solution containing indium ions. A borofluoride bath, an organic acid bath, an acidic sulfate bath, or the like can be adopted as a plating solution according to the present embodiment. More specifically, for example, the plating solution has an indium compound content of 5 to 7%, an organic acid content of 5 to 7%, an inorganic acid content of 3 to 7%, a water content of 80 to 90%, and the like.

As shown in FIG. 2, the anode holder 40 and the substrate holder 30 are arranged so as to face each other. The paddle 45 is arranged between the anode holder 40 and the substrate holder 30 and is configured to swing in a horizontal direction along a surface of a substrate. Application of a voltage between the anode and the substrate by a power source (not shown) causes a current to flow between the anode and the substrate via the plating solution to form an indium plating film on the substrate. An anode according to the present embodiment is made of, for example, titanium coated with iridium oxide or titanium coated with platinum.

The plating bath 50 and the management bath 60 are configured so as to be in fluid communication with each other through a conduit (not shown). The management bath 60 and the dissolution bath 70 are configured so as to be in fluid communication with each other through a conduit (not shown). For this reason, the plating bath 50 is in fluid communication with the dissolution bath 70 via the management bath 60. Each of the conduits connecting the plating bath 50 to the management bath 60 and connecting the management bath 60 to the dissolution bath 70 can be provided with a valve which opens or closes the conduit, means for transporting the plating solution, such as a pump, a temperature controller which adjusts the temperature of the plating solution in the conduit, a filter for filtering the plating solution in the conduit, and the like.

As shown in FIG. 2, indium metal 65 can be immersed in the acidic plating solution containing indium ions held in the dissolution bath 70. In the present embodiment, the indium metal 65 has the form of a sphere having a particle size not less than 1 mm and not more than 20 mm.

A method for indium-plating a substrate in the plating unit 110 shown in FIG. 2 will be described. First, an acidic plating solution containing indium ions is put in each of the plating bath 50, the management bath 60, and the dissolution bath 70. The anode holder 40 holding an anode and the substrate holder 30 holding a substrate are arranged in the plating bath 50 so as to face each other. Application of a voltage to the anode and the substrate by the power source (not shown) causes a current to flow between the anode and the substrate to plate a surface of the substrate with indium.

During the plating of the substrate, the plating solution is circulated between the plating bath 50 and the management bath 60, and temperature management of the plating solution, filtering of the plating solution, and the like are performed. As the plating of the substrate progresses, indium ions in the plating solution in the plating bath 50 and the management bath 60 are consumed, and indium concentration decreases. For this reason, indium ions need to be periodically supplied to the plating solution.

As described above, a plurality of methods for supplying indium ions to a plating solution have conventionally been known. However, in a method which supplies a concentrated indium solution to a plating solution, plating processing has high running costs, and the concentration of anionic species in the plating solution may rise to adversely affect the plating solution and a plating film. A case where indium metal is dissolved by electrolysis needs a facility for electrolytic dissolution and suffers from the problem of increase in the complexity of the configuration of a plating apparatus. If an insoluble anode is used, as in the present embodiment, indium ions cannot be supplied to a plating solution by a soluble anode containing indium metal. To cope with the above-described conventional problems, the present inventors have found that immersion of the indium metal 65 in an acidic plating solution causes the indium metal 65 to dissolve in the plating solution.

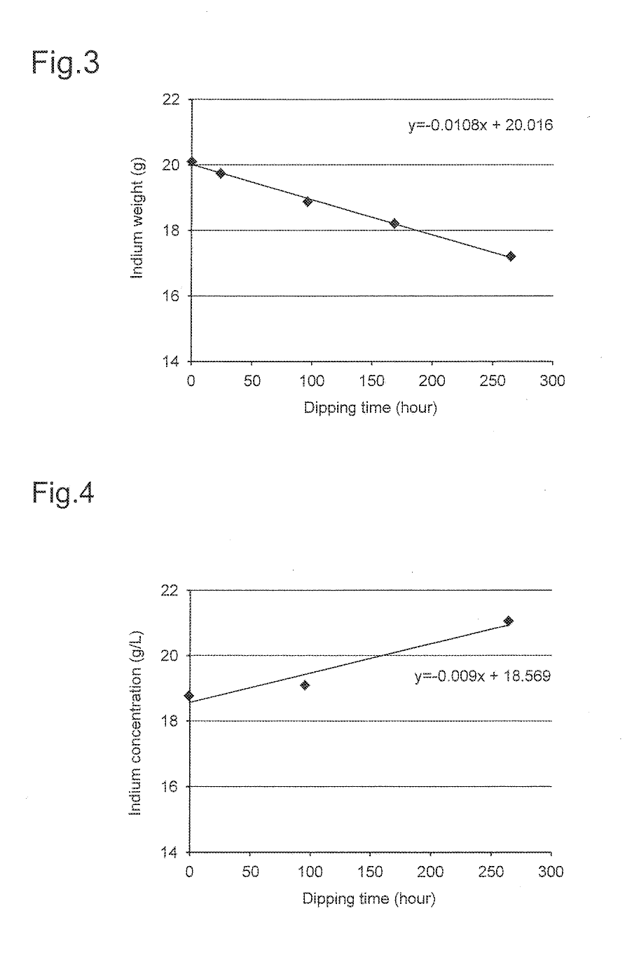

FIG. 3 is a graph showing the amount of decrease in indium metal with respect to time when the indium metal is immersed in an acidic indium plating solution. More specifically, the graph shown in FIG. 3 shows the amount of decrease in the indium metal when 20 g of indium metal having a metal particle size not less than 1 mm and not more than 20 mm and a metal purity of 99.99% is immersed in a liter of an acidic plating solution at a temperature of 30° C., and the plating solution is stirred. As shown in FIG. 3, when the indium metal was immersed in the acidic plating solution, the amount of decrease in the indium metal per day with respect to 1 g of the indium metal was about 0.26 g/day.

FIG. 4 is a graph showing change of indium metal concentration in an acidic indium plating solution with respect to time when indium metal is immersed in the plating solution. More specifically, the graph shown in FIG. 4 shows change of indium concentration under the same conditions as the graph shown in FIG. 3, i.e., the amount of dissolution of the indium metal. As shown in FIG. 4, the amount of dissolution of the indium metal in the acidic plating solution per day with respect to 1 g of the indium metal when the indium metal was immersed in the plating solution was about 0.22 g/day.

Note that the amount of decrease in the indium metal shown in FIG. 3 is larger than the amount of dissolution of the indium metal shown in FIG. 4. This is supposedly because sludge more unlikely to dissolve in the plating solution than the indium metal was formed by an amount corresponding to a difference between the amount of decrease and the amount of dissolution. The sludge is presumed to be a compound of the indium metal with the plating solution. The amount of decrease and the amount of dissolution shown in FIGS. 3 and 4 are expected to increase by increasing the amount of indium metal to be charged into the plating solution, increasing the surface area of the indium metal to be changed into the plating solution, circulating the plating solution (increasing a circulating flow rate), increasing a rate of stirring, and raising the temperature of the plating solution.

As has been described with reference to FIGS. 3 and 4, the indium metal 65 shown in FIG. 2 dissolves without voltage application to the indium metal 65 by being immersed in the acidic plating solution in the dissolution bath 70. Indium ion concentration in the plating solution in the dissolution bath 70 is thus higher than indium ion concentration in the plating solution in the management bath 60. For this reason, the indium ion concentration in the plating solution in the management bath 60 can be raised by circulating the plating solution between the management bath 60 and the dissolution bath 70. Since the plating solution circulates between the management bath 60 and the plating bath 50, indium ion concentration in the plating solution in the plating bath 50 can be raised. More specifically, for example, if the indium ion concentration in the plating solution in the plating bath 50 is measured, and the indium ion concentration falls below a predetermined value, the plating solution can be circulated between the management bath 60 and the dissolution bath 70, and the plating solution in the dissolution bath 70 can be supplied into the plating bath 50 via the management bath 60. In the above-described manner, indium ions can be supplied to the plating solution in the plating bath 50 in the present embodiment.

The indium metal 65 may be immersed in the dissolution bath 70 while being put in a bag, a basket, or the like which indium ions permeate. In this case, if supply of indium ions to the plating solution in the management bath 60 needs to be stopped, the bag or basket holding the indium metal 65 may be taken out from the dissolution bath 70. Alternatively, supply of indium ions to the management bath 60 may be stopped by stopping circulation of the plating solution between the management bath 60 and the dissolution bath 70. In this manner, supply of indium ions to the management bath 60 and the plating bath 50 can be controlled, and indium ion concentration in the plating solution can be easily adjusted.

As has been described above, in the plating apparatus according to the present embodiment, immersion of the indium metal 65 in an acidic plating solution allows supply of indium ions to the plating solution without voltage application to the indium metal 65. For this reason, indium ions can be simply and inexpensively supplied to a plating solution. Since indium metal itself can be dissolved in the present embodiment, the concentration of unnecessary anionic species in a plating solution can be prevented from rising.

As has been described in the present embodiment, a plating solution is stirred in the dissolution bath 70 while the indium metal 65 is immersed in the plating solution. This allows increase in a rate of dissolution of the indium metal 65. Additionally, the indium metal 65 having the form of a sphere having a particle size not less than 1 mm and not more than 20 mm is used in the present embodiment. If the indium metal 65 has a particle size less than 1 mm, the indium metal 65 has a larger surface area per volume and a greater likelihood of dissolving, but the small particle size increases handling difficulty. If the indium metal 65 has a particle size more than 20 mm, the indium metal 65 has a smaller surface area per volume, and the rate of dissolution is too low.

As has been described with reference to FIGS. 3 and 4, when the indium metal 65 is dissolved in an acidic plating solution, sludge is formed. Since sludge is relatively low in a rate of dissolution in a plating solution, the sludge formed in the dissolution bath 70 may move to the plating bath 50 via the management bath 60. If such sludge is deposited on a substrate in the plating bath 50, the sludge may cause defective plating of the substrate. For this reason, it is preferable to prevent sludge formed in the dissolution bath 70 from moving to the plating bath 50.

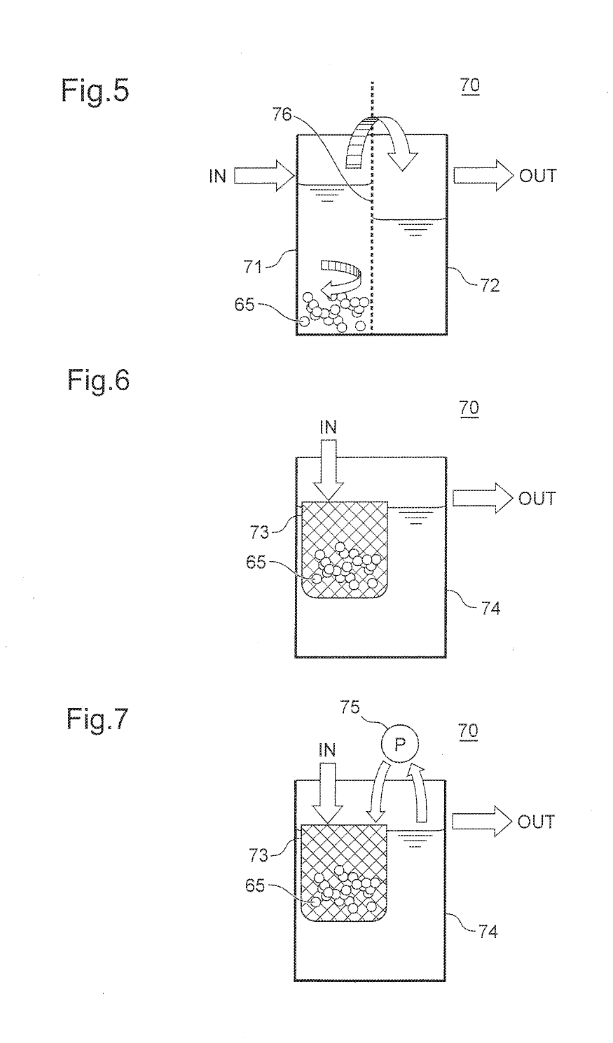

FIG. 5 is a schematic view showing the dissolution bath 70 of the plating unit 110 according to another embodiment. The plating bath 50 and the management bath 60 used in the plating unit 110 are the same as those shown in FIG. 2. As shown in FIG. 5, the dissolution bath 70 is composed of a metal dissolution bath 71 and a sludge settlement bath 72. The metal dissolution bath 71 and the sludge settlement bath 72 are divided by a partition 76. As shown in FIG. 5, the indium metal 65 is immersed in the metal dissolution bath 71.

A plating solution from the management bath 60 first enters into the metal dissolution bath 71. In the metal dissolution bath 71, the plating solution is stirred, and the indium metal 65 dissolves in the plating solution. Since the plating solution is stirred, formed sludge is dispersed in the plating solution in the metal dissolution bath 71 at this time. The plating solution in the metal dissolution bath 71 is transferred together with the formed sludge to the sludge settlement bath 72 by a pump or the like (not shown). Since the plating solution is not stirred in the sludge settlement bath 72, the sludge in the plating solution settles down. A supernatant fluid of the plating solution in the sludge settlement bath 72 is transferred to the management bath 60 by a pump or the like (not shown). As described above, the dissolution bath 70 shown in FIG. 5 can prevent formed sludge from being transferred to the management bath 60 and the plating bath 50.

FIG. 6 is a schematic view showing the dissolution bath 70 of the plating unit 110 according to another embodiment. The plating bath 50 and the management bath 60 used in the plating unit 110 are the same as those shown in FIG. 2. The dissolution bath 70 shown in FIG. 6 includes a dissolution bath main body 74 and a separate bath 73 which is provided inside the dissolution bath main body 74. Inside the separate bath 73, the indium metal 65 is immersed. The separate bath 73 is constructed by, for example, surrounding a basket made of metallic mesh or the like with an ion-exchange membrane.

A plating solution from the management bath 60 first enters into the separate bath 73. In the separate bath 73, the indium metal 65 dissolves in the plating solution. Note that the plating solution in the separate bath 73 may be stirred at this time. Indium ions in the plating solution in the separate bath 73 can move to the plating solution in the dissolution bath main body 74 through the ion-exchange membrane. Sludge formed in the separate bath 73 cannot permeate the ion-exchange membrane and stays in the separate bath 73. The plating solution with increased indium concentration in the dissolution bath main body 74 is transferred to the management bath 60 by a pump or the like (not shown). As described above, the dissolution bath 70 shown in FIG. 6 can prevent the formed sludge from being transferred to the management bath 60 and the plating bath 50.

FIG. 7 is a schematic view showing the dissolution bath 70 of the plating unit 110 according to another embodiment. The dissolution bath 70 shown in FIG. 7 is different from the dissolution bath 70 shown in FIG. 6 only in that a pump 75 is provided. More specifically, in the dissolution bath 70 shown in FIG. 7, the process of returning a plating solution in the dissolution bath main body 74 into the separate bath 73 is performed by the pump 75. With this process, it is possible to prevent sludge from moving to the management bath 60 and the plating bath 50, circulate a plating solution between the dissolution bath main body 74 and the separate bath 73, and increase a rate of dissolution of indium metal in the separate bath 73.

The embodiments of the present invention have been described above. The above-described embodiments of the invention are intended to facilitate understanding of the present invention and are not intended to limit the present invention. It is needless to say that the present invention may be changed and improved without departing from the gist thereof, and equivalents thereof are included in the invention. The components described in the claims and the specification can be arbitrarily combined or omitted as long as at least a part of the above-described problems can be solved or at least a part of effects can be exerted.

Several aspects disclosed in the present specification will be described below.

According to a first aspect, there is provided a method for supplying an indium ion to a plating solution for electrolytic plating using an insoluble anode and plating a substrate using the plating solution. The method includes a step of preparing a plating apparatus including a plating bath configured to contain the insoluble anode and the substrate such that the insoluble anode and the substrate face each other and an indium metal dissolution bath in fluid communication with the plating bath, a step of preparing an acidic plating solution, a step of immersing indium metal in the plating solution held in the indium metal dissolution bath and dissolving the indium metal in the plating solution without voltage application to the indium metal, and a step of supplying the plating solution in the indium metal dissolution bath, in which the indium metal is dissolved, to the plating bath.

According to the first aspect, it is possible to supply indium ions to the acidic plating solution to perform plating by immersing the indium metal in the plating solution. For this reason, indium ions can be simply and inexpensively supplied to the plating solution. Since the indium metal itself can be dissolved, the concentration of unnecessary anionic species in the plating solution can be prevented from rising.

According to a second aspect, the method according to the first aspect further includes a step of stirring the plating solution, in which the indium metal is immersed, in the indium metal dissolution bath. The second aspect allows increase in a rate of dissolution of the indium metal.

According to a third aspect, in the method according to the first or second aspect, the indium metal has a particle size not less than 1 mm and not more than 20 mm. If the indium metal has a particle size less than 1 mm, the indium metal has a larger surface area per volume and a greater likelihood of dissolving, but the small particle size increases handling difficulty. If the indium has a particle size more than 20 mm, the indium metal has a smaller surface area per volume, and the rate of dissolution is too low. Thus, the third aspect allows maintenance of sufficient ease of handling and the sufficient rate of dissolution.

According to a fourth aspect, the method according to any one of the first to third aspects further includes a step of separating sludge formed when the indium metal is dissolved in the plating solution in the indium metal dissolution bath from the plating solution, in which the insoluble anode and the substrate are immersed. According to the fourth aspect, since the sludge formed when the indium metal is dissolved in the plating solution is separated from the plating solution, in which the substrate is immersed, defective plating that may be caused by deposition of the sludge on the substrate can be prevented.

According to a fifth aspect, in the method according to any one of the first to fourth aspects, the step of supplying the plating solution in the indium metal dissolution bath to the plating bath includes a step of supplying the plating solution in the indium metal dissolution bath, in which the indium metal is dissolved, to the plating bath if indium ion concentration in the plating solution in the plating bath falls below a predetermined value.

According to a sixth aspect, there is provided a plating apparatus. The plating apparatus includes a plating bath which is configured to contain an insoluble anode and a substrate such that the insoluble anode and the substrate face each other and an indium metal dissolution bath which is in fluid communication with the plating bath. The indium metal dissolution bath is configured to hold a plating solution in which indium metal is dissolved without voltage application to the indium metal.

### REFERENCE SIGNS LIST

30 substrate holder
40 anode holder
50 plating bath
60 management bath
65 indium metal
70 dissolution bath
110 plating unit

What is claimed is:

1. A method for supplying an indium ion to a plating solution for electrolytic plating using an insoluble anode and plating a substrate using the plating solution, comprising:
a step of preparing a plating apparatus including a plating bath configured to contain the insoluble anode and the substrate such that the insoluble anode and the substrate face each other and an indium metal dissolution bath in fluid communication with the plating bath;
a step of preparing an acidic plating solution;
a step of immersing indium metal in the plating solution held in the indium metal dissolution bath and dissolving the indium metal in the plating bath without voltage application to the indium metal; and
a step of supplying the plating solution in the indium metal dissolution bath, in which the indium metal is dissolved, to the plating bath.

2. The method according to claim 1, further comprising
a step of stirring the plating solution, in which the indium metal is immersed, in the indium metal dissolution bath.

3. The method according to claim 1, wherein
the indium metal has a particle size not less than 1 mm and not more than 20 mm.

4. The method according to claim 1, further comprising
a step of separating sludge formed when the indium metal is dissolved in the plating solution in the indium metal dissolution bath from the plating solution, in which the insoluble anode and the substrate are immersed.

5. The method according to claim 1, wherein
the step of supplying the plating solution in the indium metal dissolution bath to the plating bath comprises a step of supplying the plating solution in the indium metal dissolution bath, in which the indium metal is dissolved, to the plating bath if indium ion concentration in the plating solution in the plating bath falls below a predetermined value.
